(19) United States
(12) Patent Application Publication
(10) Pub. No.: US 2018/0331235 A1
(43) Pub. Date: Nov. 15, 2018

(54) SCHOTTKY DIODE AND MANUFACTURING METHOD THEREOF

(71) Applicant: Gpower Semiconductor, Inc., Suzhou (CN)

(72) Inventors: Yi PEI, Suzhou (CN); Xiaoyan PEI, Suzhou (CN)

(21) Appl. No.: 15/976,165

(22) Filed: May 10, 2018

(30) Foreign Application Priority Data
May 12, 2017 (CN) 201710335096.0

(51) Int. Cl. H01L 29/872; H01L 29/40; H01L 29/66; H01L 21/765; H01L 29/778

(52) U.S. Cl. CPC H01L 29/872; H01L 29/404; H01L 29/7787; H01L 21/765; H01L 29/66143

(57) ABSTRACT

A Schottky diode comprises: a semiconductor layer and a three-terminal port located on a side of the semiconductor layer; the three-terminal port comprises a first electrode, a second electrode, and a third electrode located between the first electrode and the second electrode, at least a part of the second electrode extends into the semiconductor layer and forms a Schottky contact with the semiconductor layer, the second electrode and the third electrode are electrically connected to form an anode of the Schottky diode, and the first electrode is in ohmic contact with the semiconductor layer as a cathode of the Schottky diode; when the Schottky diode is subjected to a reverse bias voltage, a depletion layer is formed under the third electrode.

### CROSS-REFERENCE TO RELATED APPLICATIONS

The present application claims priority to Chinese Patent Application No. 201710335096.0, filed on May 12, 2017, all contents of which are incorporated by reference herein.

### TECHNICAL FIELD

Embodiments of the present invention relate to the field of semiconductor technology, and in particular, to a Schottky diode and a manufacturing method thereof.

### BACKGROUND

The third-generation semiconductor material, gallium nitride (GaN), as a wide bandgap semiconductor material, has characteristics of large forbidden band width, high electron saturation drift speed, high breakdown field strength, and good thermal conductivity and so on, which has become a current research hotspot. In terms of electronic devices, gallium nitride materials are more suitable for manufacturing high-temperature, high-frequency, high-voltage, and high-power devices than silicon and gallium arsenide. Gallium nitride electronic devices have a good application prospect.

GaN Schottky diodes are commonly used in the field of power electronics, which impose a high requirement on the power consumption of the diodes, for example, it is required that Gallium nitride Schottky diodes can withstand a large voltage in reverse, and have a small reverse leakage and a small turn-on voltage.

Traditional GaN Schottky diodes generally increase reverse voltage withstand value and reduce leakage by increasing the Schottky barrier height. However, increasing the Schottky barrier height will result in an increase in forward turn-on voltage of the diodes.

### SUMMARY

Embodiments of the present invention are directed toward a semiconductor layer and a manufacturing method thereof, which may improve reverse voltage withstand value and reduce reverse leakage current while ensuring that the forward turn-on voltage does not degrade.

A Schottky diode according to the embodiments of the present invention comprises: a semiconductor layer; a three-terminal port located on a side of the semiconductor layer; the three-terminal port comprises a first electrode, a second electrode, and a third electrode located between the first electrode and the second electrode, at least a part of the second electrode extends into the semiconductor layer and forms a Schottky contact with the semiconductor layer, the second electrode and the third electrode are electrically connected to form an anode of the Schottky diode, and the first electrode is in ohmic contact with the semiconductor layer as a cathode of the Schottky diode; when the Schottky diode is subjected to a reverse bias voltage, a depletion layer is formed under the third electrode.

In an embodiment, the third electrode is located at a preset distance from the second electrode.

In an embodiment, the preset distance makes the third electrode relatively far from the first electrode and close to the second electrode.

In an embodiment, the Schottky diode further comprises one or more field plates extending in at least one direction of the third electrode and the first electrode, extending portions are located between the first electrode and the third electrode.

In an embodiment, the one or more field plates comprise a first field plate, and the first field plate is electrically connected to the first electrode and extends toward the third electrode.

In an embodiment, the one or more field plates further comprise a second field plate located above the first field plate, and the second field plate is electrically connected to the first electrode and extends toward the third electrode.

In an embodiment, the one or more field plates comprise a third field plate, and the third field plate is electrically connected to the third electrode and extends toward the first electrode.

In an embodiment, the one or more field plates further comprise a fourth field plate located above the third field plate, and the fourth field is electrically connected to the third electrode and extends toward the first electrode.

In an embodiment, the Schottky diode further comprises a dielectric layer located between the third electrode and the semiconductor layer.

In an embodiment, the semiconductor layer comprises a barrier layer, a side of the second electrode near the third electrode comprises a first inclined surface, and the first inclined surface obliquely intersects with an upper surface of the barrier layer to form a first inclination angle.

In an embodiment, the semiconductor layer further comprises a channel layer located on a side of the barrier layer, the second electrode extends into the barrier layer or the channel layer, a side of the second electrode near the third electrode further comprises a second inclined surface, and the second inclined surface obliquely intersects with one or two of the barrier layer and the channel layer to form a second inclination angle.

In an embodiment, the first inclination angle is less than or equal to the second inclination angle.

A manufacturing method of a Schottky diode according to the embodiments of the present invention comprises comprises: providing a semiconductor layer; forming a first electrode which is in ohmic contact with the semiconductor layer on the semiconductor layer as a cathode of the Schottky diode; forming a second electrode which is in Schottky contact with the semiconductor layer on the semiconductor layer; forming a third electrode located between the first electrode and the second electrode on the semiconductor layer; electrically connecting the second electrode and the third electrode, the second electrode and the third electrode together serving as an anode of the Schottky diode; when the Schottky diode is subjected to a reverse bias voltage, a depletion layer is formed under the third electrode.

In an embodiment, the manufacturing method further comprises: forming a first field plate electrically connected to the first electrode and extending toward the third electrode on the first electrode.

In an embodiment, the manufacturing method further comprises: forming a second field plate located above the first field plate, electrically connected to the first electrode and extending toward the third electrode on the first electrode.

In an embodiment, the manufacturing method further comprises: forming a third field plate electrically connected to the third electrode and extending toward the first electrode on the third electrode.

In an embodiment, the manufacturing method further comprises: forming a fourth field plate located above the third field plate, electrically connected to the third electrode and extending toward the first electrode on the third electrode.

In an embodiment, the semiconductor layer comprises a substrate, a buffer layer located on a side of the substrate, and a channel layer located on a side of the buffer layer away from the substrate and a barrier layer located on a side of the channel layer away from the buffer layer, the manufacturing method further comprises: depositing a passivation layer on the barrier layer.

In an embodiment, forming a second electrode which is in Schottky contact with the semiconductor layer on the semiconductor layer comprises: etching the passivation layer to form a first window; etching the semiconductor layer under the first window to form a second window; forming a second electrode which is in Schottky contact with the semiconductor layer on the first window and the second window.

In an embodiment, forming a third electrode located between the first electrode and the second electrode on the semiconductor layer comprises: etching the passivation layer to form a third window between the first electrode and the second electrode; depositing a dielectric layer on the first passivation layer and the third window; forming a third electrode on the dielectric layer of the third window.

In the Schottky diodes according to the embodiments of the present invention, the second electrode and the third electrode are electrically connected as an anode, and the first electrode is used as a cathode. When the anode is forward biased, the 2DEG continuously gathers in the region near the second electrode. When the turn-on voltage of the Schottky diode is reached, the forward current rapidly increases. When the anode is reversely biased, it undergoes two stages: when the reverse bias voltage is less than the MIS structure threshold voltage of the third electrode of the Schottky diode, the depletion layer under the third electrode is not sufficient to pinch off the channel layer, and the reverse bias characteristics of the Schottky diode at this stage are the same as those of the traditional Schottky diode; after the reverse bias voltage exceeds the MIS structure threshold voltage of the third electrode of the Schottky diode, the 2DEG in the channel layer under the third electrode is depleted, that is, the channel layer is pinched off by the depletion layer, and the depletion layer gradually expands toward both directions as the reverse bias voltage increases. Since the depletion layer has a high resistance characteristic and there are few internally movable free electrons, the Schottky diodes according to the embodiments have a higher reverse voltage withstand capability and a lower leakage current than traditional Schottky diodes utilizing a Schottky junction to withstand reverse bias voltage while ensuring that the forward turn-on voltage does not degrade.

### BRIEF DESCRIPTION OF DRAWINGS

FIG. 1 is a schematic diagram illustrating a Schottky diode according to an embodiment of the present invention.

FIG. 2 is a schematic diagram illustrating a Schottky diode according to another embodiment of the present invention.

FIG. 3 is a schematic diagram illustrating a Schottky diode according to still another embodiment of the present invention.

FIG. 4 is a schematic diagram illustrating a Schottky diode according to still another embodiment of the present invention.

FIG. 5 is a schematic diagram illustrating a Schottky diode according to still another embodiment of the present invention.

FIG. 6 is a schematic diagram illustrating a Schottky diode according to still another embodiment of the present invention.

FIG. 7 is a flowchart illustrating a manufacturing method of a Schottky diode according to an embodiment of the present invention.

FIGS. 8 (a)-8 (l) are schematic diagrams illustrating each component of the Schottky diode manufactured by the manufacturing method according to the embodiment shown in FIG. 7 in each step.

FIG. 9 is a flowchart illustrating sub-steps included in step S150 shown in FIG. 7.

FIG. 10 is a flowchart illustrating sub-steps included in step S170 shown in FIG. 7.

FIG. 11 is a flowchart illustrating a manufacturing method of a Schottky diode according to another embodiment of the present invention.

FIG. 12 is a flowchart illustrating a manufacturing method of a Schottky diode according to still another embodiment of the present invention.

### DETAILED DESCRIPTION

In the following detailed description, embodiments will be described with reference to the accompanying drawings. However, the present invention may be embodied in various different forms, and should not be construed as being limited only to the illustrated embodiments. Rather, these embodiments are provided as examples, simply by way of illustrating the concept of the present invention to those skilled in the art. Accordingly, processes, elements, and techniques that should be apparent to those of ordinary skill in the art are not described herein.

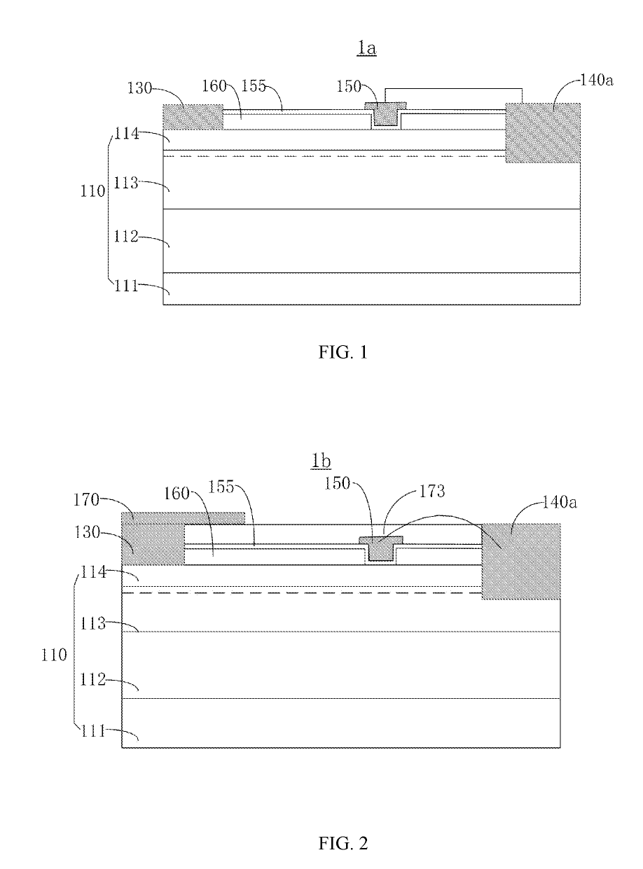

FIG. 1 is a schematic diagram illustrating a Schottky diode according to an embodiment of the present invention. As shown in FIG. 1, the Schottky diode 1a includes a semiconductor layer 110, a first electrode 130, a second electrode 140a and a third electrode 150. The first electrode 130, the second electrode 140a and the third electrode 150 are located on one side of the semiconductor layer 110 to form a three-terminal port.

The semiconductor layer 110 may be a monolayer, bilayer, or multilayer structure composed of one or more semiconductor materials. In an embodiment, the semiconductor layer 110 includes a substrate 111, a buffer layer 112, a channel layer 113 and a barrier layer 114. It may be understood that the semiconductor layer 110 may also include more or less layers in other embodiments or other semiconductor structures.

The substrate 111 plays a role of supporting the buffer layer 112. The substrate 111 may be made of sapphire, silicon carbide (SiC), silicon (Si), lithium niobate, rare earth oxides, gallium nitride (GaN), or any other suitable materials. For example, the substrate 111 may be made of Si.

The buffer layer 112 is on a side of the substrate 111. The buffer layer 112 is made of at least one of indium aluminum gallium nitride (InAlGaN), aluminum gallium nitride (AlGaN), indium aluminum nitride (InAlN), aluminum nitride (AlN), gallium nitride (GaN), and other semiconductor materials. For example, the buffer layer 112 is a GaN layer.

The channel layer 113 is located on a side of the buffer layer 112 away from the substrate 111 to provide a two-dimensional electron gas (2DEG) movement channel. The channel layer 113 may be one or more of non-doped, n-type doped or n-type locally doped GaN, AlₓGa₁₋ₓN, InₓAl₁₋ₓN and AlN, 0<x<1. For example, the channel layer 113 is an unintentionally doped GaN layer.

The barrier layer 114 is located on a side of the channel layer 113 away from the buffer layer 112. The barrier layer 114 may be one or more of Al_{y}Ga_{1-y}N, In_{y}Al_{1-y}N and AlN, 0<y<1. For example, the barrier layer 114 is an unintentionally AlGaN layer. The channel layer 113 and the barrier layer 114 combine to form a heterojunction structure, and the 2DEG is formed near the channel layer 113 at the heterojunction interface.

The first electrode 130 and the second electrode 140a are located on a side of the semiconductor layer 110. For example, the first electrode 130 may be located on a side of the barrier layer 114 of the semiconductor layer 110 away from the channel layer 113. The bottom of the first electrode 130 may extend inside the barrier layer 114 or the channel layer 113 of the semiconductor layer 110. Optionally, the bottom of the first electrode 130 is above the formed two-dimensional electron gas (2DEG). The second electrode 140a may be located on a side of the barrier layer 114 of the semiconductor layer 110 away from the channel layer 113. The bottom of the second electrode 140a may extend inside the barrier layer 114 or the channel layer 113 of the semiconductor layer 110. The bottom of the second electrode 140a may be above the formed two-dimensional electron gas (2DEG), or may be inside or below the 2DEG. The type of contact between the first electrode 130 and the semiconductor layer 110 is an ohmic contact. The type of contact between the second electrode 140a and the semiconductor layer 110 is a Schottky contact. The first electrode 130 and the second electrode 140a may be made of one or more metal materials such as nickel (Ni), aluminum (Al), titanium (Ti), gold (Au) and so on. For example, the first electrode 130 may be made of a titanium-aluminum-nickel-gold alloy after being annealed at a high temperature. The material of the second electrode 140a may be Ni.

Optionally, a first passivation layer 160 is further included between the first electrode 130 and the second electrode 140a. The first passivation layer 160 is located on the semiconductor layer 110. The first passivation layer 160 may be made of one or more materials of silicon nitride, silicon oxide, aluminum nitride and aluminum oxide.

The third electrode 150 is located between the first electrode 130 and the second electrode 140a. The cross-section of the third electrode 150 may be rectangular, T-shaped or the like. The third electrode 150 may be made of one or more metal materials such as nickel (Ni), aluminum (Al), titanium (Ti), gold (Au) and the like. For example, the third electrode 150 may be made of a nickel-gold alloy. The third electrode 150 may be a single layer of metal, or may be a stack of multiple layers of metal.

In an embodiment, a dielectric layer 155 is further included between the third electrode 150 and the semiconductor layer 110, so the third electrode 150, the dielectric layer 155 and the semiconductor layer 110 form a Metal-Insulator-Semiconductor (MIS) structure. The dielectric layer 155 acts as both a passivation layer and an insulation layer, which may effectively reduce the leakage current of the third electrode 150 and adjust the turn-on voltage of the channel layer 113. The dielectric layer 155 may be made of at least one of the high dielectric constant materials such as silicon nitride (SiN), silicon dioxide (SiO₂), silicon oxynitride (SiON), aluminum oxide (Al₂O₃), hafnium oxide (HfO₂), hafnium aluminum oxide (HfAlOₓ) or the like.

The second electrode 140a and the third electrode 150 are electrically connected to form an anode of the Schottky diode 1a. The second electrode 140a and the third electrode 150 may be, but are not limited, electrically connected by one or more metals and other conductive materials. The first electrode 130 is in ohmic contact with the semiconductor layer 110 as a cathode of the Schottky diode 1a.

With the above arrangement, when a reverse bias voltage is applied to the second electrode 140a of the Schottky diode 1a, since the third electrode 150 is electrically connected to the second electrode 140a, a negative bias is applied to the third electrode 150 and the two-dimensional electron gas in channel layer 113 under the third electrode 150 is gradually depleted. Furthermore, when the negative bias voltage applied to the third electrode 150 continues to increase and reaches its threshold voltage, the channel layer 113 under the third electrode 150 is completely pinched off by the depletion layer. As the reverse bias voltage applied to the second electrode 140a of the Schottky diode 1a continues to increase, the depletion layer under the third electrode 150 gradually widens to both sides, the reverse bias voltage applied to the Schottky diode 1a is mainly borne by the depletion layer under the third electrode 150 at this time. Since the depletion layer has a high resistance characteristic and there are few internally movable free electrons, the Schottky diode 1a according to the embodiment of the present invention has a stronger reverse voltage withstand capability and a smaller leakage current compared to a traditional Schottky diode that utilizes a Schottky junction to withstand a reverse bias voltage.

Optionally, in order to reduce the reverse bias voltage of the second electrode 140a and make the reverse bias voltage applied to the device close to the position where the second electrode 140a is located, the third electrode 150 is located at a preset distance from the second electrode 140a. In an embodiment, the preset distance makes the third electrode 150 relatively far from the first electrode 130 and close to the second electrode 140a. Preferably, the preset distance between the third electrode 150 and the second electrode 140a is less than half of the distance between the third electrode 150 and the first electrode 130.

When the positive bias voltage applied to the anode of the Schottky diode 1a reaches a certain value, the Schottky diode 1a current rapidly increases, and the Schottky diode 1a is turned on at this time. In an embodiment, in order to reduce the influence of the third electrode 150 on the two-dimensional electron gas distribution near the second electrode 140a, the distance between the third electrode 150 and the second electrode 140a needs to be greater than or equal to 1.1 um. Therefore, the forward turn-on voltage of the Schottky diode 1a according to the embodiment of the present invention does not degrade. In this way, it is ensured that the withstand voltage may be increased and the leakage current may be reduced without affecting the forward turn-on voltage.

Embodiments of the present invention also provide other Schottky diodes which further include one or more field plates based on the Schottky diode 1a shown in FIG. 1.

The field plates may be made of a conductive material such as metal simple substance, alloy or composite metal, and the specific material may be determined according to the process and device requirements. The thickness and length of the field plates are determined according to the process and device design requirements, which are not limited herein. The number of the field plates may be one, two, or more, which is not limited herein. The field plates may be uniform field plates, step field plates, multi-layer field plates, double-layer field plates and single-layer field plates. The field plates may be connected in various ways, for example, connected to the first electrode 130, connected to the third electrode 150, connected to the first electrode 130 and the third electrode 150 at the same time, individually connected to an independent potential, or not connected to any potential as floating plates.

The field plate electrically connected to the first electrode 130 and/or the third electrode 150 extends in the direction of the third electrode 150 and/or the first electrode 130, and the extending portion is located between the first electrode 130 and the third electrode 150, so that the electric field near the third electrode 150 can be modulated, and the expansion of the depletion layer under the third electrode 150 to the second electrode 140a can be suppressed, which further reduces the influence of the third electrode 150 on the two-dimensional electron gas near the second electrode 140a. Finally, the withstand voltage of the Schottky diode is increased.

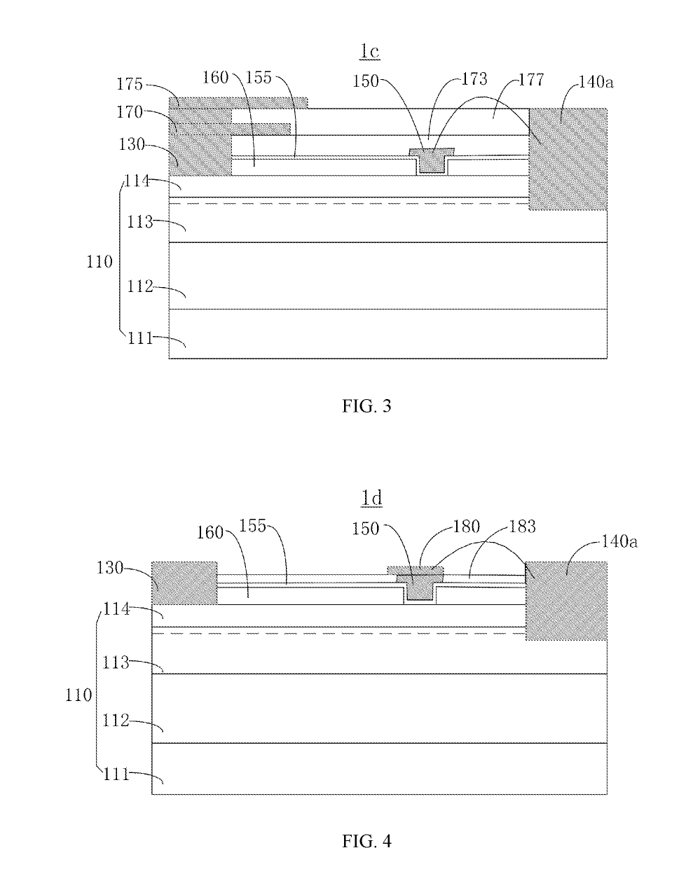

FIG. 2 is a schematic diagram illustrating a Schottky diode according to an embodiment of the present invention. As shown in FIG. 2, the Schottky diode 1b includes a first field plate 170. The first field plate 170 is electrically connected to the first electrode 130 and extends toward third electrode 150. Optionally, the first field plate 170 does not exceed the edge of the third electrode 150 near the first electrode 130.

Optionally, the Schottky diode 1b shown in FIG. 2 further includes a second passivation layer 173 between the first electrode 130 and the second electrode 140a. The second passivation layer 173 is located above the dielectric layer 155 and the third electrode 150 and below the first field plate 170.

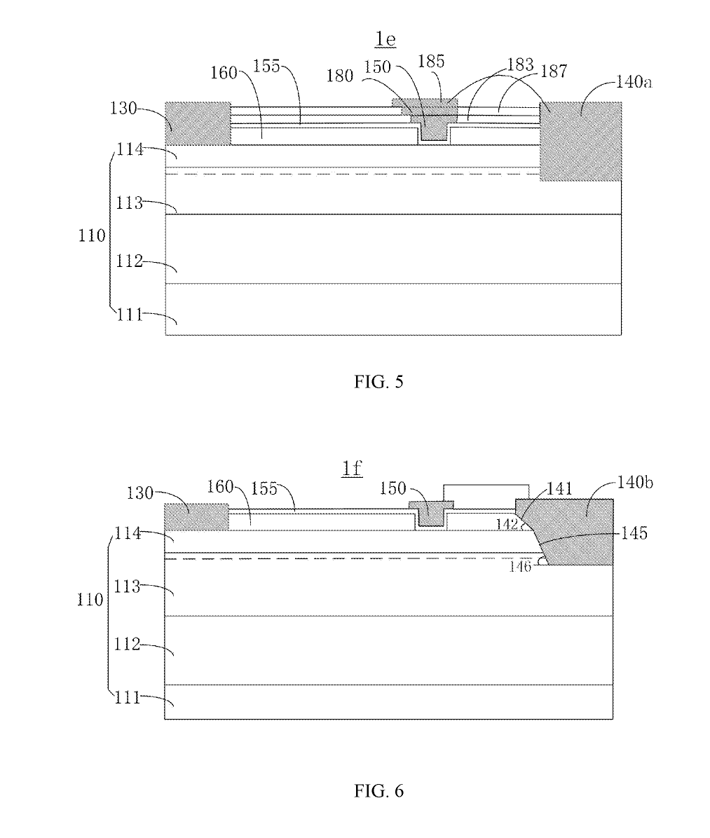

FIG. 3 is a schematic diagram illustrating a Schottky diode according to another embodiment of the present invention. As shown in FIG. 3, the Schottky diode 1c may further include a second field plate 175. The second field plate 175 is located above the first field plate 170, is electrically connected to the first electrode 130, and extends toward the third electrode 150. Optionally, the second field plate 175 does not exceed the edge of the third electrode 150 near the first electrode 130. It may be understood that more field plates electrically connected to the first electrode 130 may also be arranged above the second field plate 175 in other embodiments.

Optionally, the Schottky diode 1c shown in FIG. 3 further includes a third passivation layer 177 located between the first electrode 130 and the second electrode 140a. The third passivation layer 177 is disposed above the first field plate 170 and the third electrode 150 and below the second field plate 175.

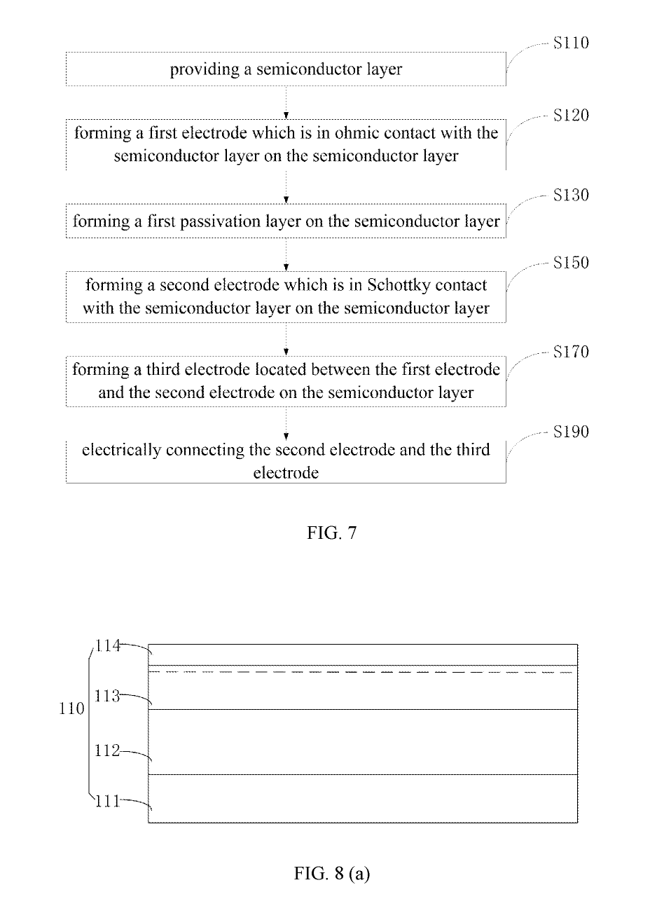

FIG. 4 is a schematic diagram illustrating a Schottky diode according to still another embodiment of the present invention. As shown in FIG. 4, the Schottky diode 1d includes a third field plate 180. The third field plate 180 is electrically connected to the third electrode 150 and extends toward the first electrode 130.

Optionally, the Schottky diode 1d shown in FIG. 4 further includes a fourth passivation layer 183 located between the first electrode 130, the third electrode 150 and the second electrode 140a. The fourth passivation layer 183 is disposed above the dielectric layer 155 and below the third field plate 180.

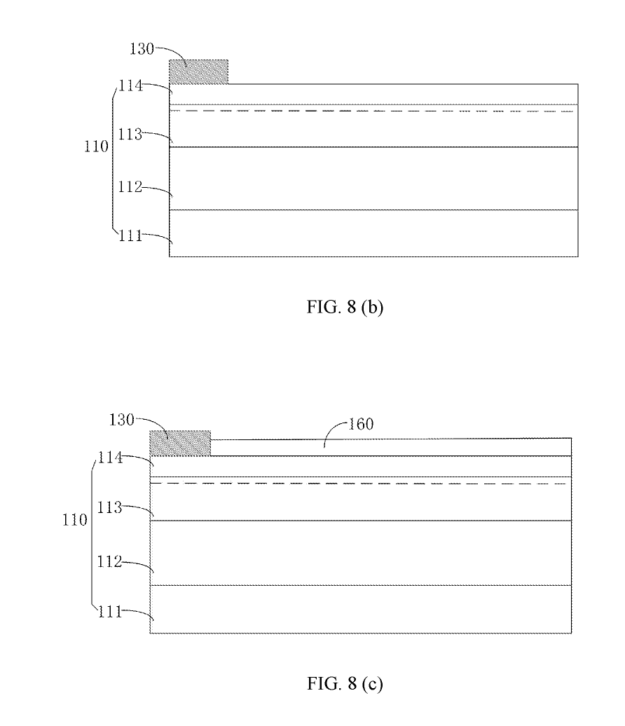

FIG. 5 is a schematic diagram illustrating a Schottky diode according to still another embodiment of the present invention. As shown in FIG. 5, the Schottky diode 1e may further include a fourth field plate 185. The fourth field plate 185 is located above the third field plate 180, is electrically connected to the third electrode 150, and extends toward the first electrode 130. It may be understood that more field plates electrically connected to the third electrode 150 may also be arranged above the fourth field plate 185 in other embodiments.

Optionally, the Schottky diode 1e shown in FIG. 5 further includes a fifth passivation layer 187 located between the third electrode 150 and the second electrode 140a. Optionally, the fifth passivation layer 187 may also be located between the first electrode 130, the third electrode 150 and the second electrode 140a. The fifth passivation layer 187 is disposed above the fourth passivation layer 183 and below the fourth field plate 185.

The second passivation layer 173, the third passivation layer 177, the fourth passivation layer 183 and the fifth passivation layer 187 may be made of one or more materials of silicon nitride, silicon oxide, aluminum nitride and aluminum oxide.

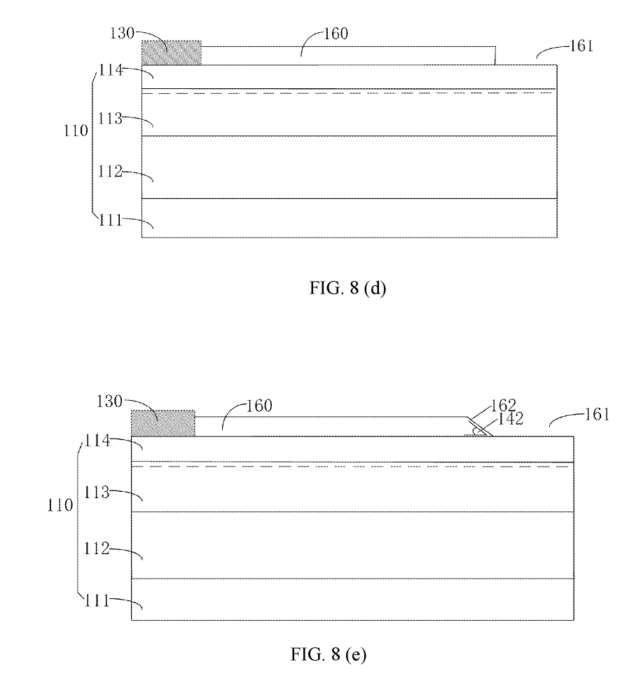

FIG. 6 is a schematic diagram illustrating a Schottky diode according to an embodiment of the present invention. The present embodiment is substantially the same as the embodiment shown in FIG. 1 except that a side of a second electrode 140b near the third electrode 150 includes a first inclined surface 141, and the first inclined surface 141 obliquely intersects with an upper surface of the barrier layer 114 to form a first inclination angle 142. In one example, the first inclined surface 141 may be formed on a side wall of the second electrode 140b. At this time, the second electrode 140b may be located on a side of the barrier layer 114 of a semiconductor layer 110 away from the channel layer 113. The bottom of the second electrode 140b may be above the formed two-dimensional electron gas (2DEG), or may be inside or below the formed 2DEG.

Optionally, when the second electrode 140b extends into the barrier layer 114 or the channel layer 113, a side of the second electrode 140b near the third electrode 150 further includes a second inclined surface 145. The second inclined surface 145 obliquely intersects with the barrier layer 114 and/or the channel layer 113 to form a second inclination angle 146. For example, the second electrode 140b extends to the barrier layer 114, the second inclined surface 145 obliquely intersects with the barrier layer 114, and the second inclination angle 146 may be an included angle between the second inclined surface 145 and the barrier layer 114. For another example, the second electrode 140b extends into the channel layer 113, the second inclined surface 145 obliquely intersects with the barrier layer 114 and the channel layer 113, and the second inclination angle 146 may be an included angle between the second inclined surface 145 and the channel layer 113. For the case where the second electrode 140b extends into the channel layer 113, the second inclined surface 145 may also be oblique to the channel layer 113, and the second inclination angle 146 may be an included angle between the second inclined surface 145 and the channel layer 113.

The first inclination angle 142 and the second inclination angle 146 are not equal to 90 degrees. In order to increase the relative area of the second electrode 140b on the side far from the substrate to further optimize the modulated electric field peak, preferably, the first inclination angle 142 is set to be less than or equal to the second inclination 146.

In one embodiment, the first inclination angle 142 is greater than 25 degrees and less than 90 degrees, and preferably, the first inclination angle 142 is greater than 30 degrees and less than 86 degrees; the second inclination angle 146 is greater than 35 degrees and less than 90 degrees, and preferably, the second inclination angle 146 is greater than 40 degrees and less than 86 degrees.

Since the first inclination angle 142 and the second inclination angle 146 are no longer right angles, the electric field peak formed near the second electrode 140b of the Schottky diode 1f according to this embodiment is different from that of the Schottky diode 1a shown in FIG. 1. Adjusting the inclination angle 142 and the second inclination angle 146 may change the forward turn-on voltage of the Schottky diode 1f, and may also modulate a strong electric field near the second electrode 140b when the Schottky diode 1f is reverse biased.

It can be understood that the Schottky diodes according to the above embodiments may also be combined arbitrarily. For example, a combined Schottky diode may include not only a field plate connected to the third electrode 150 but also a field plate connected to the first electrode 130. A combined Schottky diode may include a field plate connected to the third electrode 150, and a side of the second electrode 140b near the third electrode 150 includes a first inclined surface 141 and a second inclined surface 145. For another example, a combined Schottky diode may include a field plate connected to the first electrode 130, and a side of the second electrode 140b near the third electrode 150 includes a first inclined surface 141 and a second inclined surface 145.

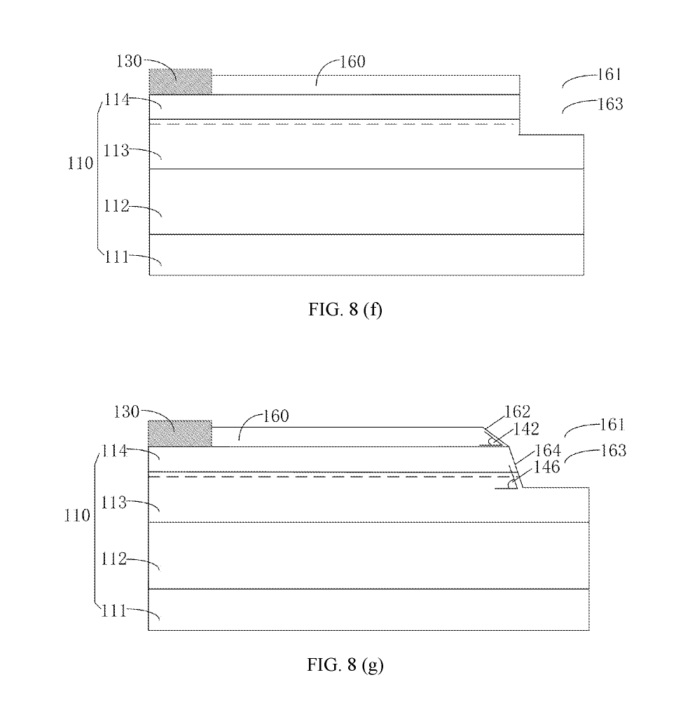

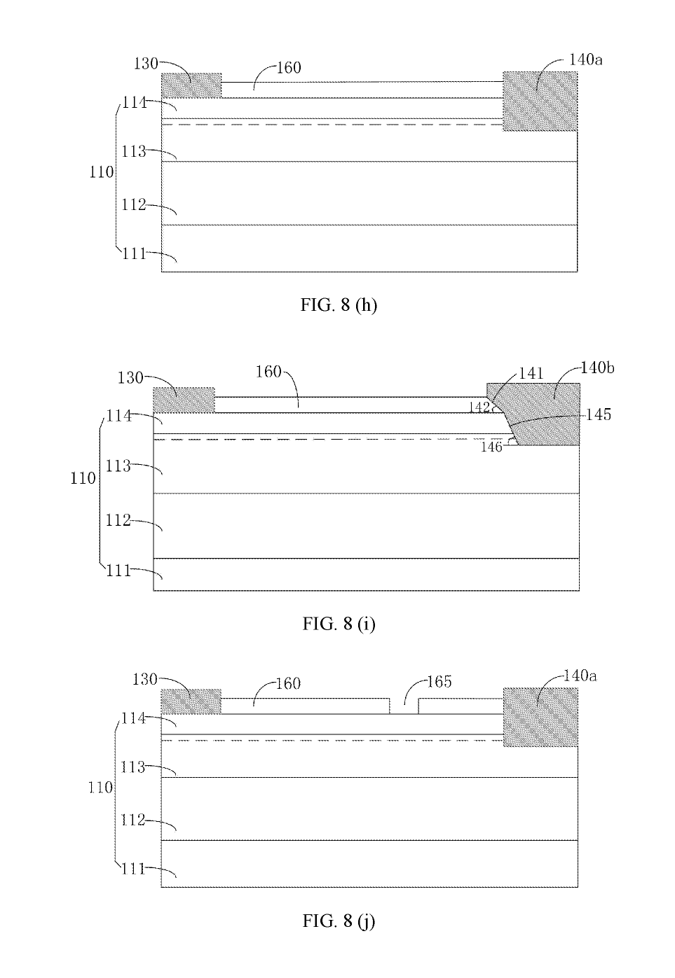

Embodiments of the present invention also provide manufacturing methods of a Schottky diode. FIG. 7 is a flowchart illustrating a manufacturing method according to an embodiment of the present invention, and FIGS. 8 (a)-8(l) are schematic diagrams illustrating each component of the Schottky diode manufactured by the manufacturing method according to the embodiment shown in FIG. 7 in each step. The specific flow shown in FIG. 7 will be described in detail below in conjunction with FIGS. 8 (a)-8(l).

Step S110: providing a semiconductor layer.

As shown in FIG. 8 (a), a semiconductor layer 110 may be a single layer, a double layer, or a multi-layer structure composed of one or more semiconductor materials. For example, the semiconductor layer 110 may be made of a substrate 111, a buffer layer 112, a channel layer 113 and a barrier layer 114 sequentially stacked. The channel layer 113 and the barrier layer 114 combine to form a heterojunction structure, and a two-dimensional electron gas (2DEG) is formed near the channel layer 113 at the heterojunction interface.

Step S120: forming a first electrode which is in ohmic contact with the semiconductor layer on the semiconductor layer.

The first electrode 130 is in ohmic contact with the semiconductor layer 110 as a cathode of the Schottky diode. The method for forming the first electrode 130 may include coating a photoresist on the semiconductor layer 110, dry etching the region of the first electrode 130 in the exposed area after development, and forming a first electrode 130 ohmic contact after evaporation, stripping, and annealing of the metal.

As shown in FIG. 8 (b), the first electrode 130 may be located on a side of the barrier layer 114 of the semiconductor layer 110 away from the channel layer 113. In addition to the location of the first electrode 130 as shown in FIG. 8 (b), it may also be that the bottom of the first electrode 130 further extends into the barrier layer 114 or the channel layer 113 of the semiconductor layer 110. Optionally, the bottom of the first electrode 130 is above the formed two-dimensional electron gas (2DEG). The first electrode 130 may be made of one or more metal materials such as nickel (Ni), aluminum (Al), titanium (Ti), gold (Au) and so on. For example, the first electrode 130 may be made of a titanium-aluminum-nickel-old alloy.

Step S130: forming a first passivation layer on the semiconductor layer.

As shown in FIG. 8 (c), the first passivation layer 160 is formed on the barrier layer 114 of the semiconductor layer 110. For example, the first passivation layer 160 may be formed by a thin film deposition process. The first passivation layer 160 may be made of one or more materials of silicon nitride, silicon oxide, aluminum nitride, and aluminum oxide.

Step S150: forming a second electrode which is in Schottky contact with the semiconductor layer on the semiconductor layer.

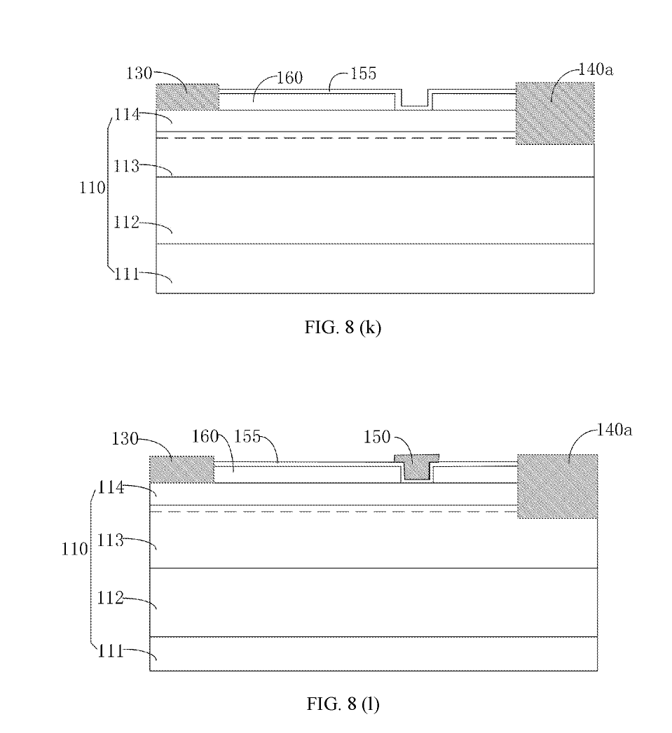

Refer to FIG. 9, optionally, step S150 may specifically include sub-step S151, sub-step S153 and sub-step S155.

Sub-step S151: etching the first passivation layer to form a first window.

The etching method of the first window 161 may be that coating a photoresist on the first passivation layer 160, and after the development, as shown in FIG. 8 (d), the first window 161 is dry etched in the exposed area to form the second electrode 140a shown in FIG. 1.

As shown in FIG. 8 (e), the first window 161 may also have a third inclined surface 162, so as to form the second electrode 140b having the first inclined surface 141 obliquely intersecting with the upper surface of the barrier layer 114 shown in FIG. 6. The inclination angle of the third inclined surface 162 may be formed by controlling the proportion of the etching gas.

Sub-step S153: etching the semiconductor layer under the first window to form a second window.

The etching method of the second window 163 may be the same as the etching method of the first window 161, and the photoresist is used to expose and etch. The etching depth of the second window 163 may be selected to exceed or not exceed two-dimensional electron gas (2DEG). As shown in FIG. 8 (0, the second window 163 may be a right angle so as to form the second electrode 140a shown in FIG. 1. As shown in FIG. 8 (g), the second window 163 may also have a fourth inclined surface 164 so as to be able to form the second electrode 140b having a second inclination surface 145 obliquely intersecting with the barrier layer 114 and/or the channel layer 113. The inclination angle of the fourth inclined surface 164 may be formed by controlling the proportion of the etching gas.

Sub-step S155: forming a second electrode which is in Schottky contact with the semiconductor layer on the first window and the second window.

In detail, the second electrode 140a (or 140b) may be formed by vaporizing metal at the first window 161 and the second window 163. According to the shapes of the first window 161 and the second window 163 formed by the sub-step S151 and the sub-step S153, the shape of the second electrode may be as shown in FIG. 8 (h) or 8 (i). The metal may have a large work function and form a Schottky junction with the semiconductor layer 110 under the second electrode 140a (or 140b). Optionally, the second electrode 140a (or 140b) may be made of nickel.

It can be understood that since the shape of the second electrode has little effect on the steps of making the third electrode 150 and electrically connecting the third electrode 150 and the second electrode 140a (or 140b), only the right-angled second electrode 140a is illustrated in the following steps.

Step S170: forming a third electrode located between the first electrode and the second electrode on the semiconductor layer.

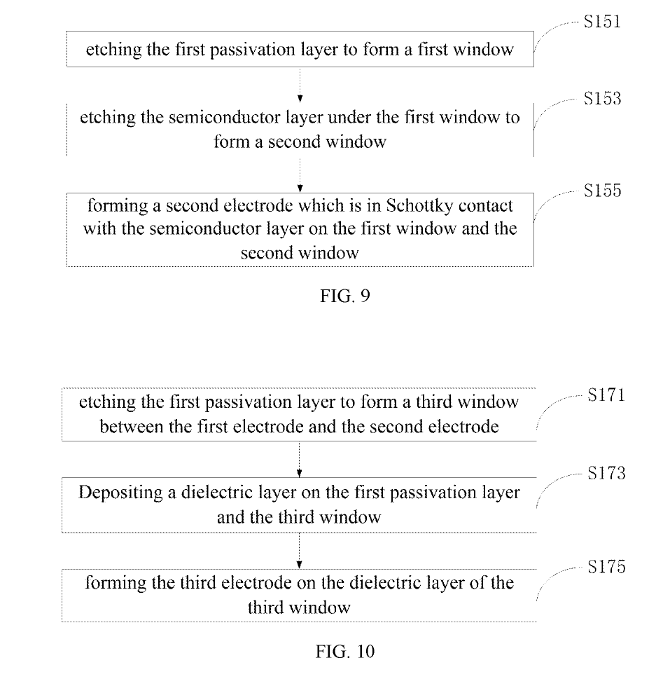

Refer to FIG. 10, optionally, step S170 may specifically include sub-step S171, sub-step S173 and sub-step S175.

Sub-step S171: etching the first passivation layer to form a third window between the first electrode and the second electrode.

As shown in FIG. 8 (j), the third window 165 may be etched to the barrier layer 114, and the third window 165 may be set at a preset distance from the second electrode 140a. The third window 165 may be formed by coating a layer of photoresist on the first passivation layer 160, exposing and developing the region of the third electrode 150, and then etching off the first passivation layer 160 in the region of the third window 165. The third window 165 is formed after the photoresist is removed.

Sub-step S173: depositing a dielectric layer on the first passivation layer and the third window.

As shown in FIG. 8 (k), the dielectric layer 155 serves as both a passivation layer and an insulation layer, which may effectively reduce the leakage current of the third electrode 150 and adjust the turn-off voltage of the channel layer. The dielectric layer 155 may be made of at least one of the high dielectric constant materials such as silicon nitride (SiN), silicon dioxide (SiO₂), silicon oxynitride (SiON), aluminum oxide (Al₂O₃), hafnium oxide (HfO₂), hafnium aluminum oxide (HfAlOₓ) and so on. The dielectric layer 155 may be formed by a thin film deposition process.

Sub-step S175: forming the third electrode on the dielectric layer of the third window.

The cross-section of the third electrode may be rectangular, T-shaped and so on. For example, as shown in FIG. 8(l), a T-shaped third electrode 150 is formed on the dielectric layer 155 of the third window 165. The third electrode 150 may be made of a nickel-gold alloy. The third electrode 150, the dielectric layer 155 and the barrier layer 114 form a Metal-Insulator-Semiconductor (MIS) structure.

Step S190: electrically connecting the second electrode and the third electrode.

For example, the second electrode 140a and the third electrode 150 may be electrically connected to form a Schottky diode 1a shown in FIG. 1. The second electrode 140a and the third electrode 150 together serve as an anode of the Schottky diode 1a. The electrical connection may be realized through one or more conductive materials such as metals.

With the above arrangement, when a reverse bias voltage is applied to the anode of the Schottky diode 1a, a depletion layer is formed under the third electrode 150 to withstand the reverse bias voltage. In this way, the reverse voltage withstand value of the Schottky diode 1a is increased and the leakage current is reduced. Furthermore, since the two-dimensional electron gas distribution near the second electrode 140a of the Schottky diode 1a is not affected by the third electrode 150, the forward turn-on voltage of the Schottky diode 1a does not degrade.

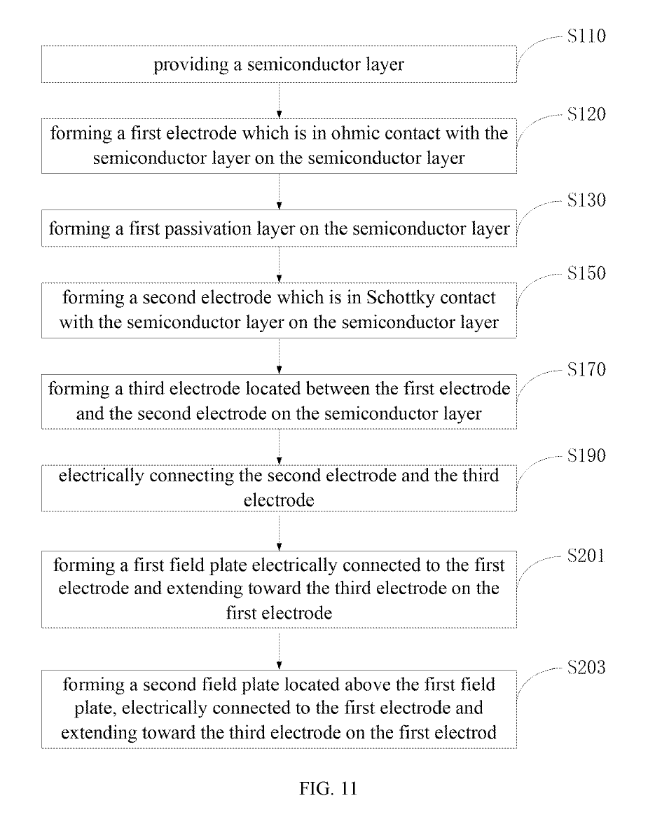

FIG. 11 is a flowchart illustrating a manufacturing method of a Schottky diode according to another embodiment of the present invention. As shown in FIG. 11, the method further includes steps S201 and S203 based on the embodiment shown in FIG. 7.

Step S201: forming a first field plate electrically connected to the first electrode and extending toward the third electrode on the first electrode.

The first field plate 170 may be formed by depositing a second passivation layer 173 on the dielectric layer 155 and the third electrode 150, and the second passivation layer 173 is located between the first electrode 130 and the second electrode 140a. A region of the first field plate 170 may be formed by photolithography. Optionally, the region of the first field plate 170 extends from the first electrode 130 toward the third electrode 150 and does not exceed the side of the third electrode 150 near the first electrode 130. After the metal is evaporated and stripped, the first field plate 170 is formed in the region of the first field plate 170 so as to form the Schottky diode 1b as shown in FIG. 2.

Step S203: forming a second field plate located above the first field plate, electrically connected to the first electrode and extending toward the third electrode on the first electrode.

The second field plate 175 may be formed by depositing a third passivation layer 177 above the first filed plate 170 and the third electrode 150. The third passivation layer 177 is located between the first electrode 130 and the second electrode 140a. A region of the second field plate 175 may be formed by photolithography. Optionally, the region of the second field plate 175 extends from the first electrode 130 over the first field plate 170 and extends toward the third electrode 150, and does not exceed one side of the third electrode 150 near the first electrode 130. After the metal is evaporated and stripped, the second field plate 175 is formed in the region of the second field plate 175 so as to form the Schottky diode 1c as shown in FIG. 3.

It can be understood that a Schottky diode including multiple field plates connected to the first electrode 130 may be further formed by repeating steps similar to steps S201 and S203.

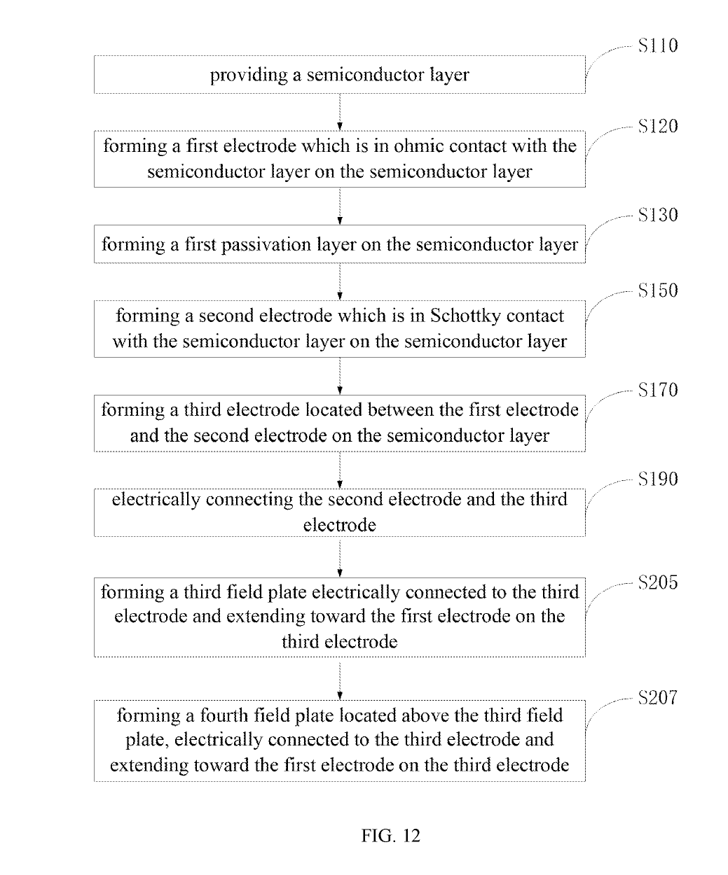

FIG. 12 is a flowchart illustrating a manufacturing method of a Schottky diode according to still another embodiment of the present invention. As shown in FIG. 12, the method further includes steps S205 and S207 based on the embodiment shown in FIG. 7.

Step S205: forming a third field plate electrically connected to the third electrode and extending toward the first electrode on the third electrode.

The third field plate 180 may be formed by depositing a fourth passivation layer 183 on the dielectric layer 155. The fourth passivation layer 183 is located between the first electrode 130, the third electrode 150 and the second electrode 140a. A region of the third field plate 180 may be formed by photolithography. Optionally, the region of the third field plate 180 extends from the third electrode 150 toward the first electrode 130. After the metal is evaporated and stripped, the third field plate 180 is formed in the region of the third field plate 180 so as to form the Schottky diode 1d as shown in FIG. 4.

Step S207: forming a fourth field plate located above the third field plate, electrically connected to the third electrode and extending toward the first electrode on the third electrode.

The fourth field plate 185 may be formed by depositing a fifth passivation layer 187 on the fourth passivation layer 183. The fifth passivation layer 187 is located between the first electrode 130, the third electrode 150 and the second electrode 140a. A region of the fourth field plate 185 may be formed by photolithography. Optionally, the region of the fourth field plate 185 extends from the third electrode 150 toward the first electrode 130. After the metal is evaporated and stripped, the fourth field plate 185 is formed in the region of the fourth field plate 185 so as to form the Schottky diode 1e as shown in FIG. 5.

It can be understood that a Schottky diode including multiple field plates connected to the third electrode 150 may be further formed by repeating steps similar to steps S205 and S207.

It can also be understood that a Schottky diode including both the field plate connected to the first electrode 130 and the field plate connected to the third electrode 150 may also be formed by repeating steps similar to steps S201, S203, S205 and S207. In addition, when the first window 161 and the second window 163 include the first inclined surface 141 and the second inclined surface 145, the formed second electrode 140b of the Schottky diode having the field plate also includes the first inclined surface 141 and the second inclined surface 145, and the cross-section of the second electrode 140b is not rectangular as shown in FIGS. 2-5.

In the Schottky diodes according to the embodiments of the present invention, the second electrode 140a (or 140b) and the third electrode 150 are electrically connected as an anode, and the first electrode 130 is used as a cathode. When the anode is forward biased, the 2DEG continuously gathers in the region near the second electrode 140a (or 140b). When the turn-on voltage of the Schottky diode is reached, the forward current rapidly increases. When the anode is reversely biased, it undergoes two stages: when the reverse bias voltage is less than the MIS structure threshold voltage of the third electrode 150 of the Schottky diode, the depletion layer under the third electrode 150 is not sufficient to pinch off the channel layer 113, and the reverse bias characteristics of the Schottky diode at this stage are the same as those of the traditional Schottky diode; after the reverse bias voltage exceeds the MIS structure threshold voltage of the third electrode 150 of the Schottky diode, the 2DEG in the channel layer 113 under the third electrode 150 is depleted, that is, the channel layer 113 is pinched off by the depletion layer, and the depletion layer gradually expands toward both directions as the reverse bias voltage increases. Since the depletion layer has a high resistance characteristic and there are few internally movable free electrons, the Schottky diodes according to the embodiments have a higher reverse voltage withstand capability and a lower leakage current than traditional Schottky diodes utilizing a Schottky junction to withstand reverse bias voltage.

In summary, the Schottky diodes according to the embodiments of the present invention have a higher reverse voltage withstand value and a lower reverse leakage current compared to the traditional Schottky diodes while ensuring that the forward turn-on voltage does not degrade.

In the description of the present invention, it should be noted that the terms “set” and “connected” should be interpreted broadly unless specifically defined or limited otherwise. For example, “connected” may be a fixed connection, a detachable connection, or an integrated connection. It may be a mechanical connection or an electrical connection. It may be directly connected or indirectly connected through an intermediate medium, and it may be an internal connection between two components. For those skilled in the art, the specific meanings of the above terms in the embodiments of the present invention may be understood according to specific cases.

In the description of the embodiments of the present invention, it should also be noted that the terms “up”, “down”, “inner”, “outer” and the like indicate the orientation or positional relationship based on the orientation or positional relationship shown in the drawings, or the orientation or positional relationship of the embodiments product when used conventionally. This is merely for convenience of describing the embodiments and simplification of the description, rather than to indicate or imply that the device or component referred to must have a specific orientation, be constructed and operated in a specific orientation, therefore it should not be understood as a limitation of the present invention.

While the present disclosure has been described with reference to exemplary embodiments, it will be apparent to those skilled in the art that various changes and modifications may be made without departing from the spirit and scope of the present invention. Therefore, the above embodiments are provided for illustrative purposes only, and should not in any sense be interpreted as limiting the scope of the present disclosure.

What is claimed is:

1. A Schottky diode, comprising:
a semiconductor layer; and
a three-terminal port located on a side of the semiconductor layer,
wherein the three-terminal port comprises a first electrode, a second electrode, and a third electrode located between the first electrode and the second electrode, at least a part of the second electrode extends into the semiconductor layer and forms a Schottky contact with the semiconductor layer, the second electrode and the third electrode are electrically connected to form an anode of the Schottky diode, and the first electrode is in ohmic contact with the semiconductor layer as a cathode of the Schottky diode;
wherein when the Schottky diode is subjected to a reverse bias voltage, a depletion layer is formed under the third electrode.

2. The Schottky diode of claim 1, wherein the third electrode is located at a preset distance from the second electrode.

3. The Schottky diode of claim 2, wherein the preset distance makes the third electrode relatively far from the first electrode and close to the second electrode.

4. The Schottky diode of claim 1, further comprising one or more field plates extending in at least one direction of the third electrode and the first electrode, wherein extending portions are located between the first electrode and the third electrode.

5. The Schottky diode of claim 4, wherein the one or more field plates comprise a first field plate, and the first field plate is electrically connected to the first electrode and extends toward the third electrode.

6. The Schottky diode of claim 5, wherein the one or more field plates further comprise a second field plate located above the first field plate, and the second field plate is electrically connected to the first electrode and extends toward the third electrode.

7. The Schottky diode of claim 4, wherein the one or more field plates comprise a third field plate, and the third field plate is electrically connected to the third electrode and extends toward the first electrode.

8. The Schottky diode of claim 7, wherein the one or more field plates further comprise a fourth field plate located above the third field plate, and the fourth field is electrically connected to the third electrode and extends toward the first electrode.

9. The Schottky diode of claim 1, further comprising a dielectric layer located between the third electrode and the semiconductor layer.

10. The Schottky diode of claim 1, wherein the semiconductor layer comprises a barrier layer, a side of the second electrode near the third electrode comprises a first inclined surface, and the first inclined surface obliquely intersects with an upper surface of the barrier layer to form a first inclination angle.

11. The Schottky diode according to claim 10, wherein the semiconductor layer further comprises a channel layer located on a side of the barrier layer, the second electrode extends into the barrier layer or the channel layer, a side of the second electrode near the third electrode further comprises a second inclined surface, and the second inclined surface obliquely intersects with one or two of the barrier layer and the channel layer to form a second inclination angle.

12. The Schottky diode according to claim 11, wherein the first inclination angle is less than or equal to the second inclination angle.

13. A manufacturing method of a Schottky diode, comprising:
providing a semiconductor layer;
forming a first electrode which is in ohmic contact with the semiconductor layer on the semiconductor layer as a cathode of the Schottky diode;
forming a second electrode which is in Schottky contact with the semiconductor layer on the semiconductor layer;
forming a third electrode located between the first electrode and the second electrode on the semiconductor layer; and
electrically connecting the second electrode and the third electrode, the second electrode and the third electrode together serving as an anode of the Schottky diode,
wherein when the Schottky diode is subjected to a reverse bias voltage, a depletion layer is formed under the third electrode.

14. The manufacturing method of claim 13, further comprising:
forming a first field plate electrically connected to the first electrode and extending toward the third electrode on the first electrode.

15. The manufacturing method of claim 14, further comprising:
forming a second field plate located above the first field plate, electrically connected to the first electrode and extending toward the third electrode on the first electrode.

16. The manufacturing method of claim 13, further comprising:
forming a third field plate electrically connected to the third electrode and extending toward the first electrode on the third electrode.

17. The manufacturing method of claim 16, further comprising:
forming a fourth field plate located above the third field plate, electrically connected to the third electrode and extending toward the first electrode on the third electrode.

18. The manufacturing method of claim 13, wherein the semiconductor layer comprises a substrate, a buffer layer located on a side of the substrate, and a channel layer located on a side of the buffer layer away from the substrate and a barrier layer located on a side of the channel layer away from the buffer layer, the manufacturing method further comprising:
depositing a passivation layer on the barrier layer.

19. The manufacturing method of claim 18, wherein forming a second electrode which is in Schottky contact with the semiconductor layer on the semiconductor layer comprises:
etching the passivation layer to form a first window;
etching the semiconductor layer under the first window to form a second window;
forming a second electrode which is in Schottky contact with the semiconductor layer on the first window and the second window.

20. The manufacturing method of claim 18, wherein forming a third electrode located between the first electrode and the second electrode on the semiconductor layer comprises:
etching the passivation layer to form a third window between the first electrode and the second electrode;
depositing a dielectric layer on the first passivation layer and the third window;
forming a third electrode on the dielectric layer of the third window.
